(19) United States
(12) Patent Application Publication
(10) Pub. No.: US 2006/0279321 A1
(43) Pub. Date: Dec. 14, 2006

(54) Control system and control method for checking the function of liquid crystal displays

(76) Inventors: Uwe Ruppender, Mannheim (DE); Karl Miltner, Frankenthal (DE); Wolfgang Obermeier, Heidelberg (IT); Edgar Baumann, Mannheim (DE); Hartmut Henkel, Kriftel (DE)

Correspondence Address: BAKER & DANIELS LLP, 300 NORTH MERIDIAN STREET, SUITE 2700, INDIANAPOLIS, IN, 46204, US

(21) Appl. No.: 10/552,544

(22) PCT Filed: Mar. 27, 2004
(86) PCT No.: PCT/EP04/03277

§ 371 Date: Oct. 12, 2005

(30) Foreign Application Priority Data
Apr. 12, 2003 (DE) 103 16 901.6

(51) Int. Cl. G01R 31/00

(52) U.S. Cl. 324/770

(57) ABSTRACT

The invention proposes a method and a measuring system for testing the function of LCD displays comprising individual display segments, based on the difference in the electrical capacitance Cseg of defective and intact display segments. The method is based on the direct determination of the capacitance of the display segments with a capacitance measuring method by measuring the stored electrical charge. As a preferred measuring method, a method is proposed, in which a charge transfer through a reference capacitor Cref proceeds and the segment capacitance Cseg is determined by means of a charge balance, preferably by means of a ΔΣ conversion.

The invention relates to a method and a corresponding electronic measuring system for testing the function of liquid crystal displays comprising individual display segments, on the basis of the difference in the electrical capacitance of defective and intact segments, in particular in medical measuring or diagnostic devices.

The faultless functioning of the display is of major significance in many applications. Defects in the measuring value display of medical-technological devices, e.g. blood sugar monitoring devices, can lead to incorrect readings and may cause life-threatening misinformation of the user, for example due to ensuing incorrect dosing of a medication, and bring about life-threatening situations.

A first example of a malfunction of this type is the failure of the decimal point in a display showing mmol/l, for example due to a defect in the line or a defect in the display. A second example is the failure of two segments causing a leading 4, e.g. in displaying a glucose reading of 415 mg, to change to a leading 1 such that the incorrect result of 115 mg is displayed.

In battery-operated devices, in particular, liquid crystal displays (LCDs) have all but displaced all other displays, since their electrical power needs are low, since they can be operated at low operating voltages, their electronic triggering is easy to implement, they provide high contrast and image quality, the shape of the display segments can be designed virtually without limitations using simple lithographic procedures, whereby even large-area segments or displays can be implemented, they have a low overall depth, and are easy to install. LCD displays of this type comprise multiple segments that can be activated individually, whereby a segment displays a character or a symbol or part of a character or signal.

In LCDs, the alphanumerical characters and symbols to be displayed are applied to a cover glass in the form of transparent front electrodes which, jointly with back electrodes applied on a carrier glass and the liquid crystal layer defined by means of spacers, form a dielectric serving as capacitor storage for electrical charges.

It is known, though, that segments or entire characters of LCDs can fail giving rise to the attendant risks mentioned above. For this reason, it is common to display the entire display of a device with an LCD display, whereby all segments are activated, for a short time of typically 2 to 4 seconds when a device is turned on. During this period of time, the user of the device can visually test whether or not all segments and/or characters and symbols are being displayed.

However, a first disadvantage is that the users often do not perform this visual test in routine practical application of the device. A second disadvantage is that, in this procedure, the display can be monitored only at the time the device is turned on and any failure of one or multiple segments during ongoing operation remains undetected by the user.

In order to overcome these disadvantages methods have been proposed, in which the electrical capacitance of the LCD segments serves as an auxiliary parameter for testing the function performance. The test is based on the change in capacitance upon incorrect function based on the fact that the capacitance of intact display segments differs from the capacitance of non-intact display segments. The capacitance is then used to conclude that the function is correct or failure is evident. A number of different measuring procedures have been proposed that are based on measuring an electrical parameter that depends on the capacitance of the display segments, for example based on the measurement of the time course of the electrical voltage on the display segment or measurement of the amplitude of the operating current.

In the document, WO 95/14238, the test of the functional performance of the LCD segments is based on their intrinsic capacitance as the parameter being measured. Any change is used to conclude that there is a failure. The LCDs are operated with alternating voltage and the operating current is what is measured. A special feature of the functional test is that the current is measured at various operating frequencies and tested whether or not the current is within predetermined limits of a range in a certain frequency range. This allows various conclusion to be drawn with regard to different states and causes of failure.

However, this known method is disadvantageous in that no interfering parasitic coupling capacitances falsifying the test are taken into consideration, and in that the method is described only for LCD displays comprising separate segment and return electrodes for each LCD display segment.

From the document, EP 0 015 914 B1, a method is known, in which the LCD display segments are monitored by triggering the LCDs with clocked voltage or alternating voltage and using the time course of the voltage to draw a conclusion with regard to the correct functioning of the segments. The measuring method is based on the fact that the capacitance changes if there is a short-circuit or defective segment resulting in a change of the rate of voltage increase or decrease. However, the method described therein is specified only for LCD displays with joint back electrode and only for the detection of line interruptions and short-circuits between segment and back electrode.

From the document, EP 0436777 A2, a method and a device for testing the LCDs of an LCD array prior to final assembly of the array are known. Herein, a charge is applied to an LCD capacitance and the charge remaining after a certain period of time is measured. The comparison of the charge that is applied versus the remaining charge is used to draw a conclusion with regard to the ability of the device to function. As a disadvantage of this prior art, neither the function of the fully assembled LCD array nor its function while it is in operation can be tested.

The document, U.S. Pat. No. 5,539,326, describes a method for testing the terminal connections of an LCD display prior to final assembly. For this purpose, the LCDs are charged in multiple steps either with or without charging the capacitance of the LCD cells themselves and the difference between these charges, determined by means of a current that is integrated over time, is used to determine whether or not the feed lines of the LCDs function properly. A test of the LCDs themselves is not performed and testing during ongoing operation is not feasible.

The document, U.S. Pat. No. 5,428,300, describes a method and a device for testing TFT-LCDs, in which various charging and discharging processes proceed and the functioning of the TFT-LCDs and their connection is determined by means of the wave mode of the discharge currents.

It is common to all previously known methods that they are based on an absolute measurement testing whether an absolute capacitance value complies with certain limits. For this reason, the known methods are disadvantageous in that they are very sensitive to temperature drifts and other drifts as well as component scattering. This is disadvantageous in particular because the capacitance of segments of LCD displays is very small.

Moreover, the previously known methods, in particular those that are based on the determination of charge time constants, often do not operate free of direct voltage, require variation of the measuring frequency, and become increasingly non-linear at low capacitance with regard to the determination of capacitance.

Taking the prior art as described above into consideration, the invention is based on the object to provide a method and a corresponding electronic measuring system for testing the function of LCD displays that allows for reliable, user-independent, fully automatic functional testing, whereby the method is to be implemented with little effort, for example by means of CMOS technology in an ASIC.

This object is achieved according to the invention by a method and/or a device with the features of the appended independent patent claims. Preferred embodiments and developments of the invention are evident from the dependent patent claims and the following description in conjunction with the corresponding drawings.

An embodiment according to the invention for testing the function of LCD displays comprising individual display segments, on the basis of the difference in the electrical capacitance of defective and intact display segments thus comprises the particularity that, instead of measuring an electrical measuring parameter that is dependent on the capacitance of the display segments and comparing the measuring value thus measured to a reference value, the capacitance of the display segments is determined directly with a capacitance measuring method by measuring the electrical charge stored in the display segment.

In the context of the present invention it was surprisingly found that the charge stored in LCD display segments can be measured such that it becomes feasible to directly determine the capacitance of the display segments at high resolution and accuracy.

The direct determination of the capacitance of LCD display segments according to the invention can be performed in a large number of ways. According to a first advantageous feature it is being proposed to determine the capacitance of the display segments by means of charges transferred by capacitive coupling, whereby an electrical measuring current is coupled capacitively via the capacitance of the display segment to be measured into an evaluation circuit and the evaluation circuit measures the charge coupled over. Herein, according to an additional preferred feature, the measuring current can be provided in the form of an alternating current and in that the charge coupled over per alternating voltage period is measured, from which results the capacitance of the display segment provided the frequency is known.

According to another preferred feature it is proposed to measure the capacitance of the display segments with a capacitance measuring method, in which a charge transfer controlled by a sequence control proceeds through both the capacitance of a display segment to be measured and a reference capacitor, and the capacitance of the display segment is determined by means of a charge balance between the display segment to be tested and the reference capacitor.

A relative measurement of this type based on the determination of a ratio of capacitances is advantageous in that it is insensitive to temperature and long-term drifts, e.g. of the reference voltage sources, and/or in that it compensates these drifts. In this context, a preferred embodiment provides, for minimization of measuring errors, the reference capacitor integrated into the LCD display, for example in the form of an LCD segment or capacitor component. This is advantageous in that it compensates for temperature drifts even better.

A preferred embodiment of the method according to the invention consists of the determination of the capacitance of the display segments by means of a capacitance measuring method utilizing a ΔΣ conversion. A method of this type is particularly suitable for measuring small capacitances. The capacitance of LCD display segments is approx. 1 pF bis 300 pF such that the charges to be measured are on the order of pC and the measuring currents are on the order of pA and thus are technically difficult to detect.

A capacitance measuring method utilizing a ΔΣconversion can be set-up with scarce use of analog electronics and at high measuring accuracy and insensitivity to parasitic scatter capacitances, for example, in the form of a first order ΔΣ converter, i.e. by using an integrator.

The basic principles of ΔΣ A/D converters and their implementation issues in connection with CMOS technology are known. The basic principle of a converter of this type is that charge packets are loaded at a constant frequency from the capacitor to be measured, i.e. an LCD segment in the case considered here, onto an integrator. Since the capacitor to be measured is recharged from a known voltage to a different known voltage, since the voltage difference generated at the capacitor to be measured is constant and known, the charge fed to the integrator with each charge transfer is proportional to the capacitance.

The output voltage of the integrator is proportional to the charge stored in the integration capacitor of the evaluation circuit and is monitored continuously according to the clock time of the voltage packets supplied. If a given voltage value is exceeded at the output of the integrator, the integrator is charged in the opposite direction by known reference charge packages. This results in a closed control circuit, in which the charge in the integrator, i.e. on its integration capacitor, is kept constant in a long-term balance. For this reason, this is often called a “charge balancing” principle and the term is used synonymous to the term, ΔΣ procedure.

The result of a conversion of this type is a 1-bit data stream whose mean density of ones is proportional to the capacitance to be measured. This data stream is then processed adequately to obtain a multi-bit event. This is typically done by means of digital filters, so-called decimation filters. According to the theory of ΔΣ converters, for analysis of a data stream of a “charge balancing” converter of a given order, in general, a decimation filter of an order higher by at least one is required. Accordingly, the preferred embodiment of a first order ΔΣ converter uses a decimation filter of second or higher order.

A control circuit for controlling the constant charge balance of the ΔΣ converter can be set up from few flip-flops and easily integrated into an ASIC. The structure of a second order decimation filter is very regular and easy to integrate into an ASIC. In other embodiments, implementation of the filter in a microcontroller, for example in the microcontroller of the sequence control, is also feasible.

According to another preferred feature it is proposed to use an automatic measuring-circuit selector to address individual display segments for the functional test. The particular advantage of the measuring-circuit selector selecting individual segments is its capacity to strongly reduce or all but exclude the influence of parasitic capacitances and coupling capacitances which usually falsify the measuring result.

In an advantageous embodiment it can be provided that the measuring-circuit selector is used to apply a measuring voltage to a first electrode of a display segment to be tested, to connect the electrodes of other display segments corresponding to said first electrode to earth in terms of alternating voltage, to measure the coupled charge on the second electrode of the display segment to be tested, whereby this point is connected to virtual earth in terms of alternating voltage, and to connect the electrodes of other display segments corresponding to said second electrode to earth in terms of alternating voltage.

It is particularly preferred for the first electrode to be the front electrode and the second electrode to be the back electrode of the display segment to be tested.

Advantageously, the method according to the invention can also be used when the display segments are triggered in a matrix structure using the multiplex procedure both for the ongoing operation of the LCD display and the functional test.

According to another advantageous feature it is proposed to select the triggering levels and clock phases for triggering the display segments, in particular in a multiplex procedure, such that the voltage level of the inactive display segments is below the response threshold and the voltage level of the active display segments is above the response threshold of the display segments, to perform the capacitance measuring method using these voltage levels, and to synchronize the switch phases of the capacitance measuring method with the clock phases of LCD triggering.

For the operation of the LCD display segments it is advantageous for the display segments to be triggered direct voltage-free, on average, by means of periodical reversal of the polarity of the voltage levels. This is because in direct voltage operation or in the presence of a fraction of direct voltage there is a risk of electrolytic effects occurring due to leakage currents, which may decompose the liquid crystals. Moreover, it is advantageous for the capacitance measuring method to be performed such that the effective voltage value of the display segment is identical to the value without measurement of the capacitance.

Moreover, it is advantageously provided that the capacitance of a display segment is measured during a clock phase of display segment triggering, whereby multiple switching processes of the capacitance measuring method are performed within this clock phase.

According to another preferred feature it is proposed to trigger the LCD display for the ongoing operation and/or capacitance measurement at low impedance in order to reduce the influence of coupling capacitances.

A particular advantage of the method according to the invention can be that the capacitance of the display segments is determined by means of the capacitance measuring method in the form of a digital measuring result and the functional test of a display segment is performed using the digital measuring result.

Another advantageous feature of the method according to the invention is that it is possible to perform the functional test of a display segment during the ongoing operation of the LCD display. An advantageous embodiment of the method according to the invention provides for only activated display segments to be tested for function, since non-activated display segments do not yield an incorrect display if malfunctioning. This allows to speed up the functional test of the LCD display segments or to repeat them at a higher frequency.

According to an additional advantageous feature the sequence control for the capacitance measurement and/or the measuring-circuit selector for addressing a display segment is modulated by and/or synchronized with the driver circuit of the LCD display.

Another advantageous feature can be that one or multiple components of the LCD test facility comprising the sequence control for capacitance measurement, the measuring-circuit selector for addressing of a display segment, the measuring circuit (analog switch, integration amplifier, and comparator and integration capacitor, if any), the LCD driver/decoder circuit, and the evaluation circuit (microcontroller) are housed in a single integrated component, e.g. an ASIC or a mixed signal FPGA. In a particular embodiment thereof, an LCD triggering circuit as usually employed for driving and decoding can be provided with the LCD testing facility according to the invention. In this context, a preferred embodiment provides for the ASIC to be integrated into an LCD driver circuit.

The method according to the invention is suitable for any LCD display-containing devices, in particular for medical measuring and diagnostic devices.

The invention and its particular embodiments comprise a multitude of advantages. They provide a digital measuring result allowing high accuracy and therefore reliable testing to be achieved. This allows the criteria for proper functioning and/or the presence of malfunction in the functional test to be selected in a very differentiated fashion, and to be analyzed by software. In the case of the relative measurement, insensitivity to temperature and long-term drifts is achieved. Moreover, series resistances, for example in the contacts, have no impact on the measuring result provided the switching periods are sufficiently long. The method according to the invention is suitable for any LCDs, i.e. it is not restricted to those with a common back electrode or with separate segment and back electrodes, but also suitable for LCDs with segment electrodes in a matrix structure.

The method according to the invention is easy to calibrate, namely by software, automatically and without changing or adjusting circuits. Calibration parameters can be determined automatically, for example in an ASIC, and stored in an EEPROM or flash ROM. In contrast, according to the prior art, the external circuits and testing frequency must be adapted to the type of the LCD display.

Automatic calibration by means of a reference LCD, reference LCD segment or reference capacitor component and/or calibration capacitor is feasible. A calibration capacitor serves for calibrating the entire measurement and/or measuring circuit. The reference capacitor is used to attain the charge balance in ΔΣ conversion. The final design of the testing facility in a device does not require a calibration capacitor.

Malfunctioning of LCD display segments can be detected automatically with the invention without the user having to inspect the display by eye. This facilitates user-independent, fully automatic testing of the LCD display and provides for high reliability for the user.

The method according to the invention can be performed very fast. A typical LCD display can be tested completely in approx. 0.5 to 1 second, including multiple scanning to improve the reliability of the result. The method can work with a constant measuring frequency and segment testing can be performed in a direct voltage-free fashion. As another advantage, the circuit according to the invention can be implemented at very low cost, in particular when it is integrated into the ASIC for triggering the LCD display.

The invention facilitates testing of the quality and functioning of LCD displays not only as part of their manufacturing process, with regard to which resource-consuming technical methods are required according to the prior art, but also provides for functional testing in a simple fashion during the serviceable life of the final device.

The test of the LCD display can proceed in a fashion that is not visually evident to the user. The LCD display can be monitored at any point in time, e.g. continuously, at the start of a measurement or when displaying a measuring result, instead of only when the device is being turned on.

A multitude of device responses to the detection of a malfunction of a display segment are feasible, for example the generation of a warning signal or preclusion of device function.

The invention is illustrated in the following based on the exemplary embodiments shown in the figures. The particularities illustrated therein can be used separately or in combination in order to create preferred developments of the invention. In the figures:

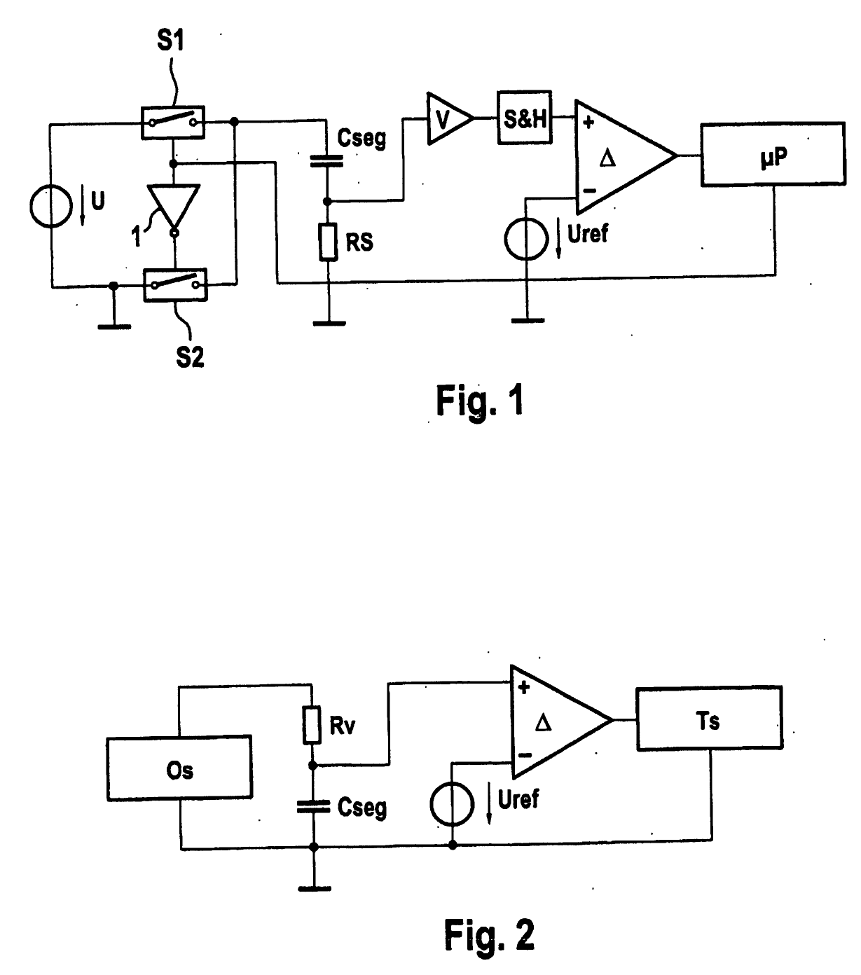

FIG. 1 shows a functional diagram of a first LCD testing facility according to the prior art;

FIG. 2 shows a functional diagram of a second LCD testing facility according to the prior art;

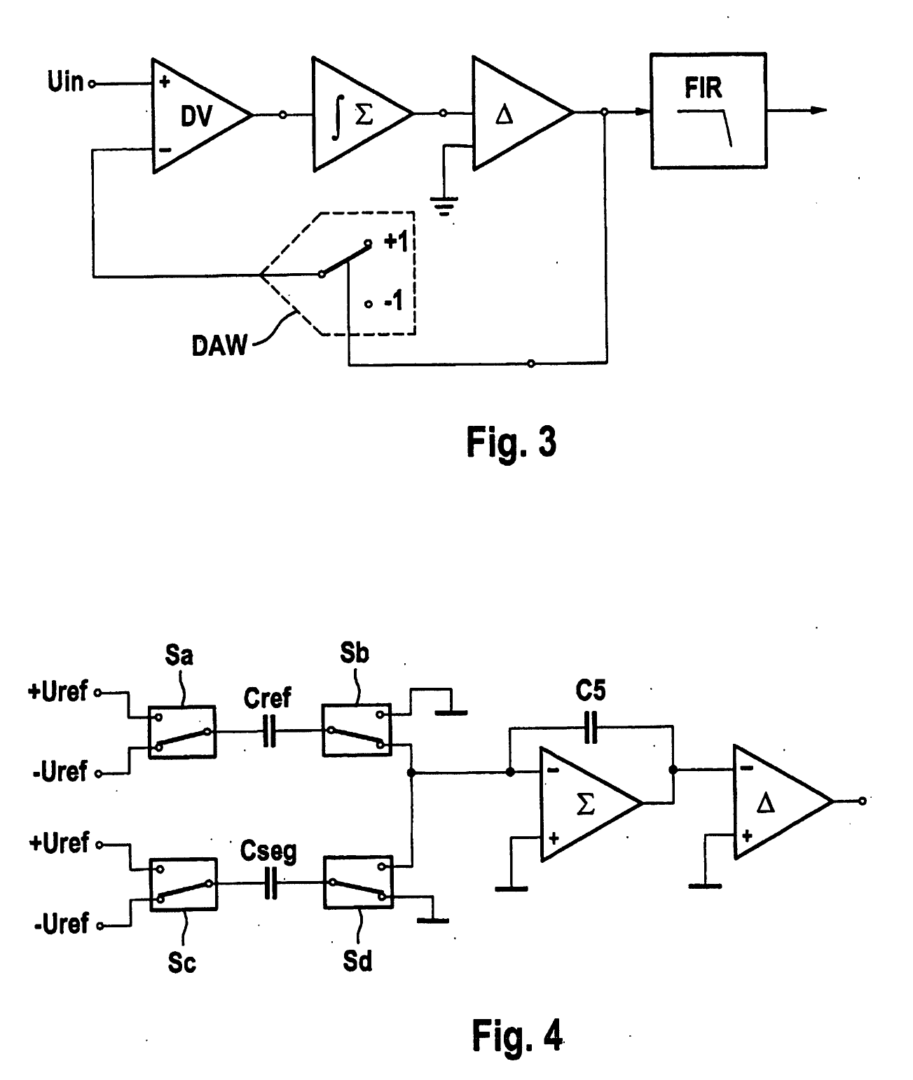

FIG. 3 shows a schematic diagram of a ΔΣ conversion;

FIG. 4 shows a schematic diagram of a preferred LCD capacitance measuring arrangement according to the invention with ΔΣ conversion;

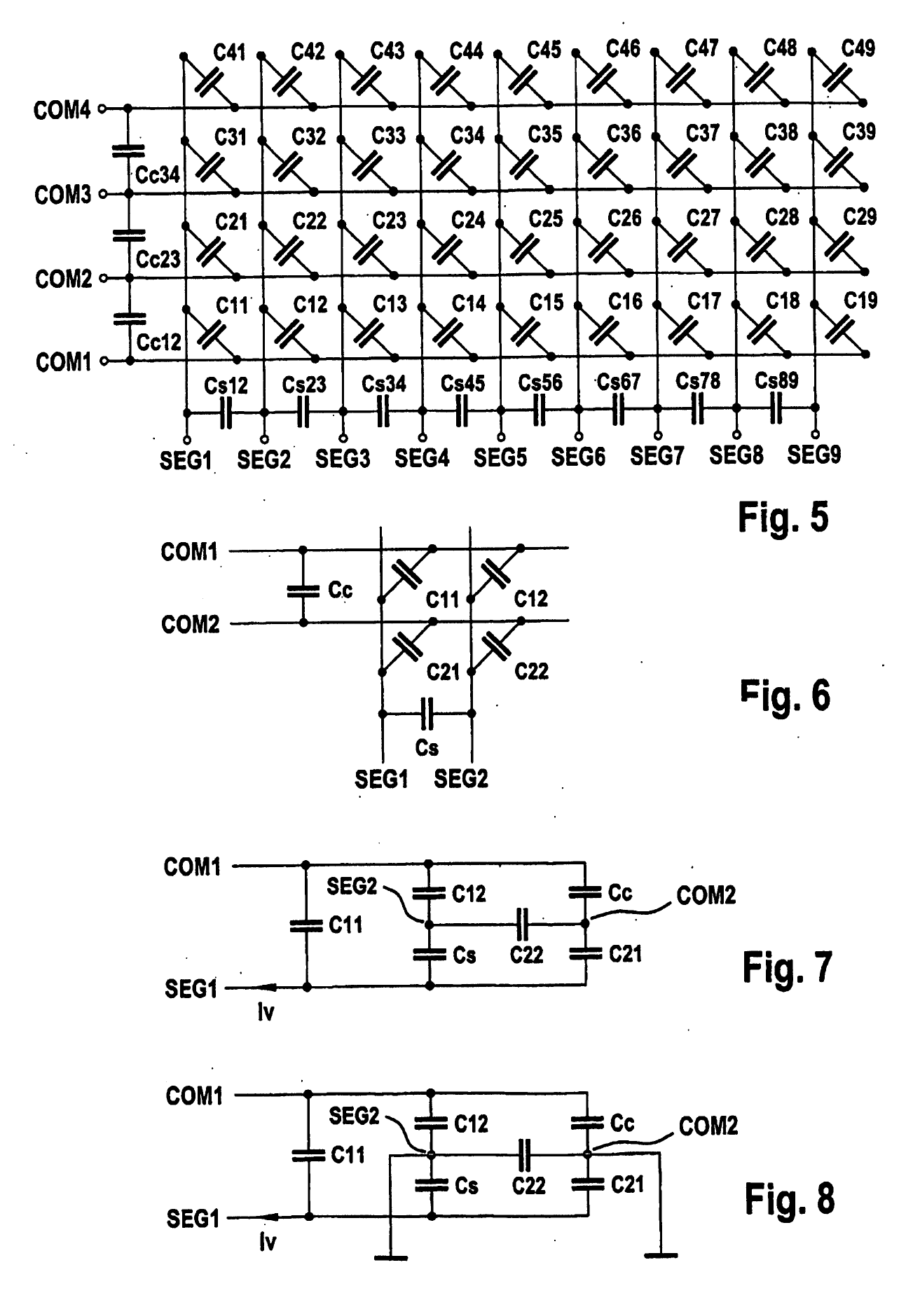

FIG. 5 shows the capacitances of a matrix arrangement of LCD display segments in a 4×9 matrix;

FIG. 6 shows the capacitances of a matrix arrangement of LCD display segments in a 2×2 matrix;

FIG. 7 shows the 2×2 matrix of FIG. 6 in two-terminal view;

FIG. 8 shows the matrix of FIG. 7 including the elimination of the influence of parasitic capacitances in the functional test;

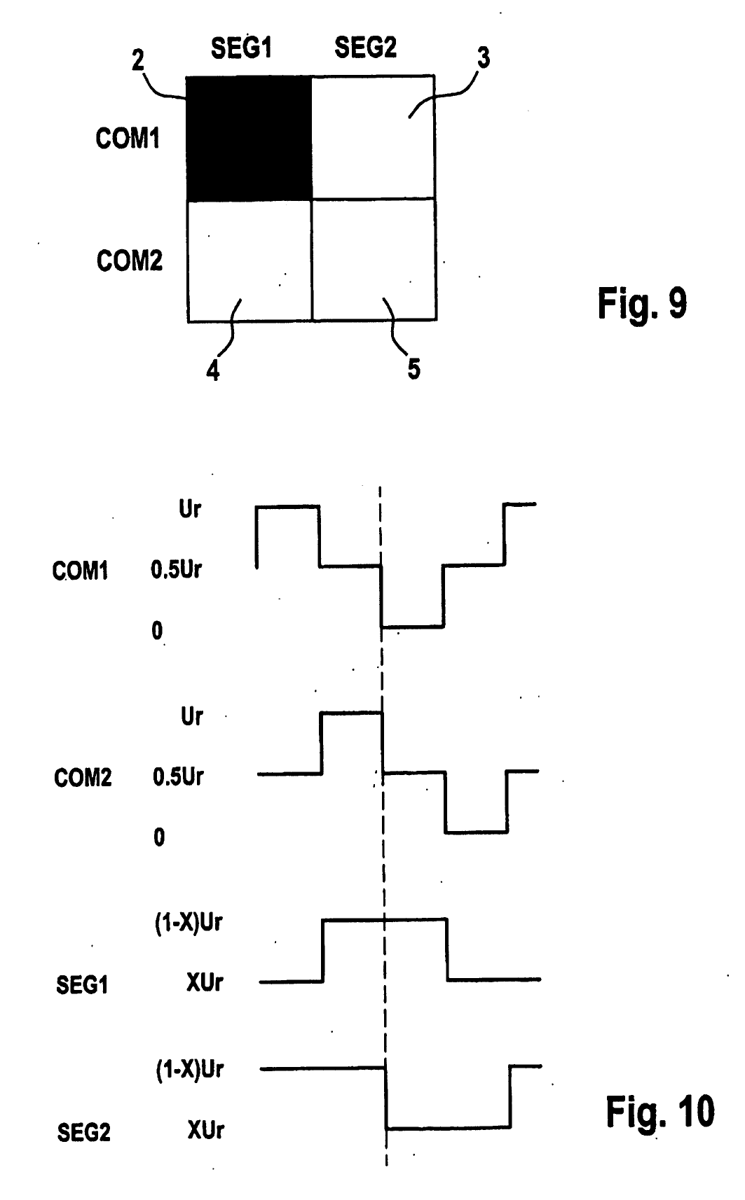

FIG. 9 shows the display segments of the LCD matrix of FIG. 6;

FIG. 10 shows LCD triggering impulses for FIG. 9;

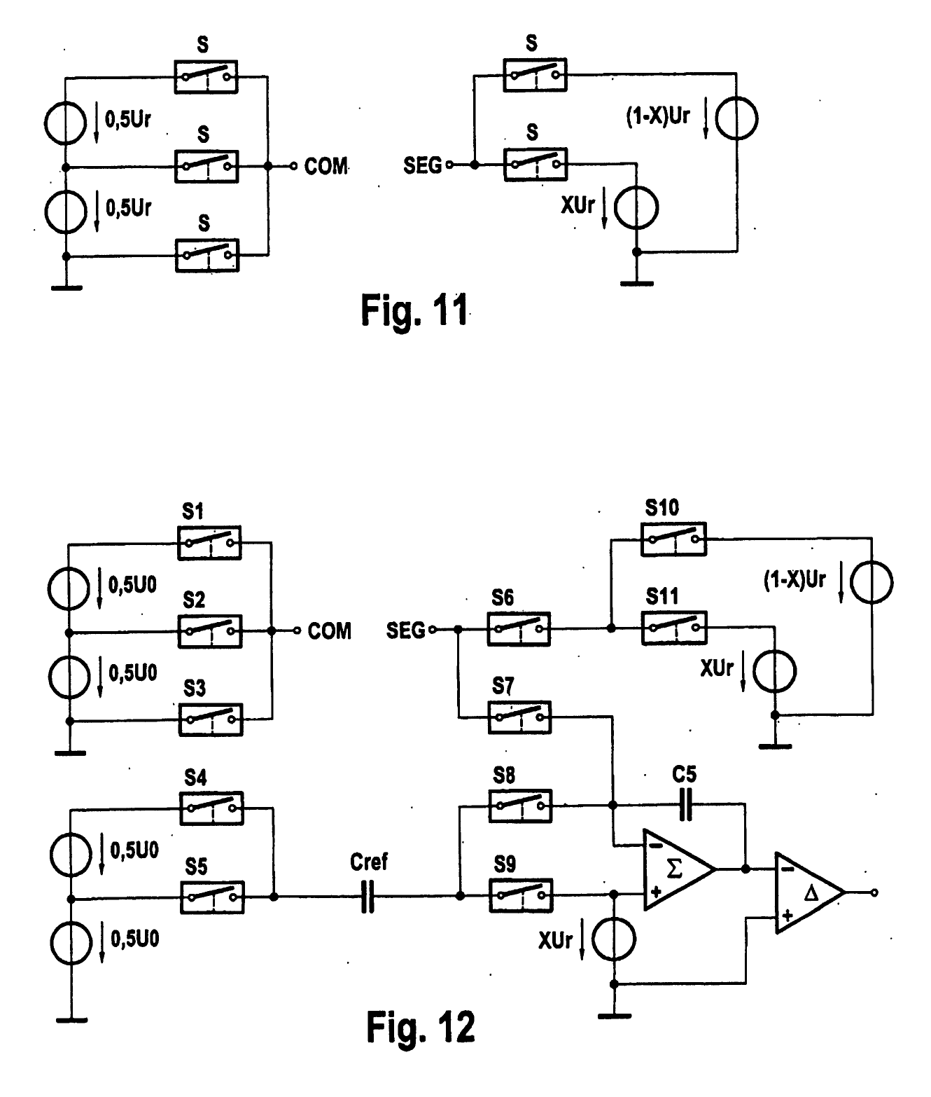

FIG. 11 shows an LCD driver circuit for the multiplex operation of FIG. 6;

FIG. 12 shows the LCD driver circuit of FIG. 11 with ΔΣ conversion according to the invention, for the testing of display segments;

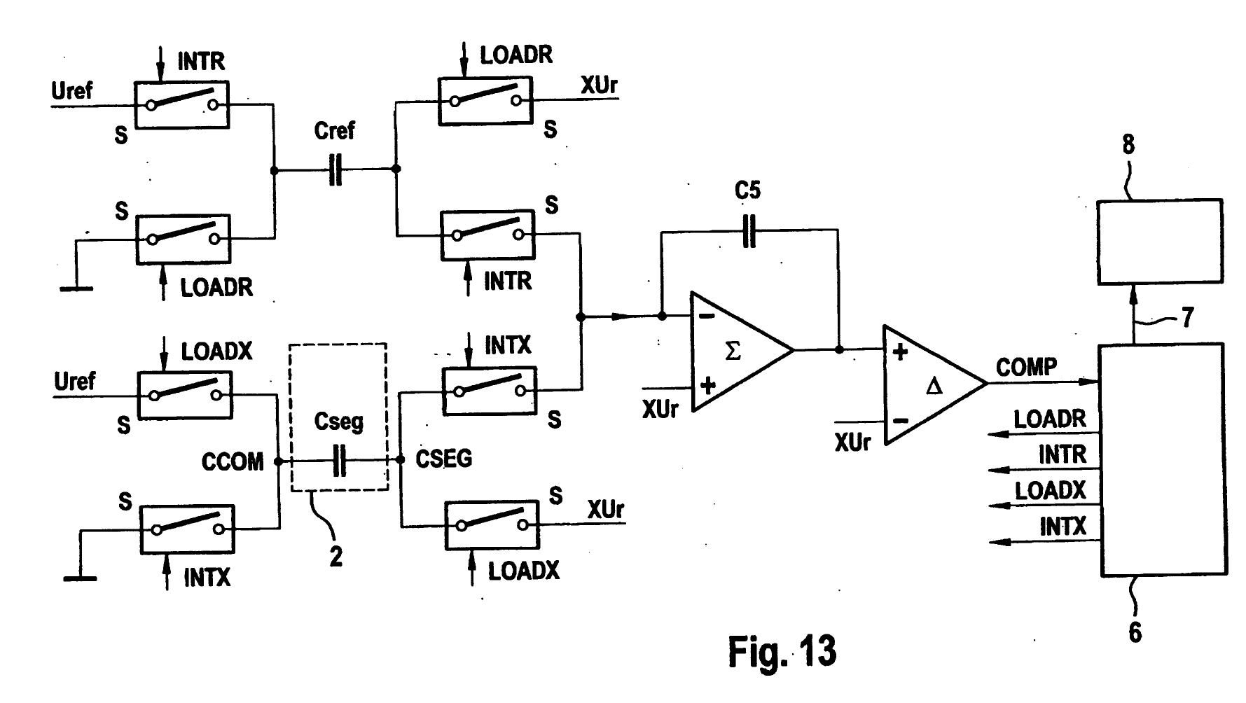

FIG. 13 shows a modified capacitance measuring circuit at rest;

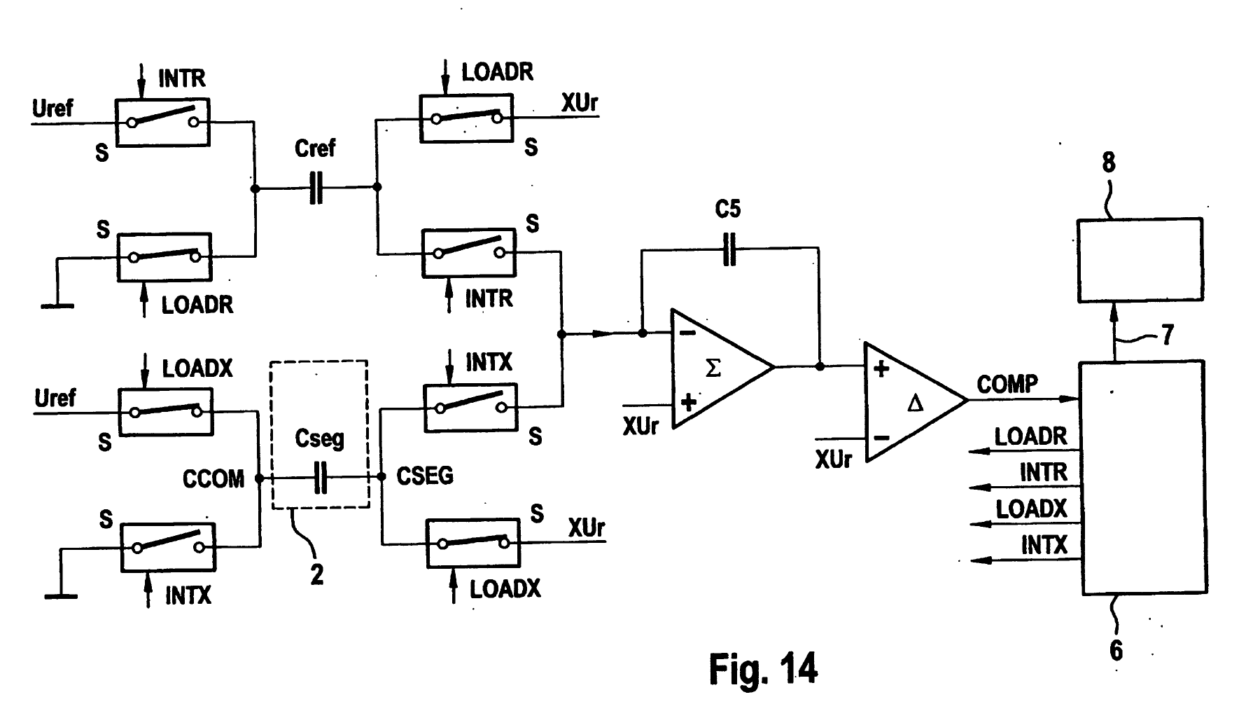

FIG. 14 shows the capacitance measuring circuit of FIG. 13 in its charging phase and comparison phase;

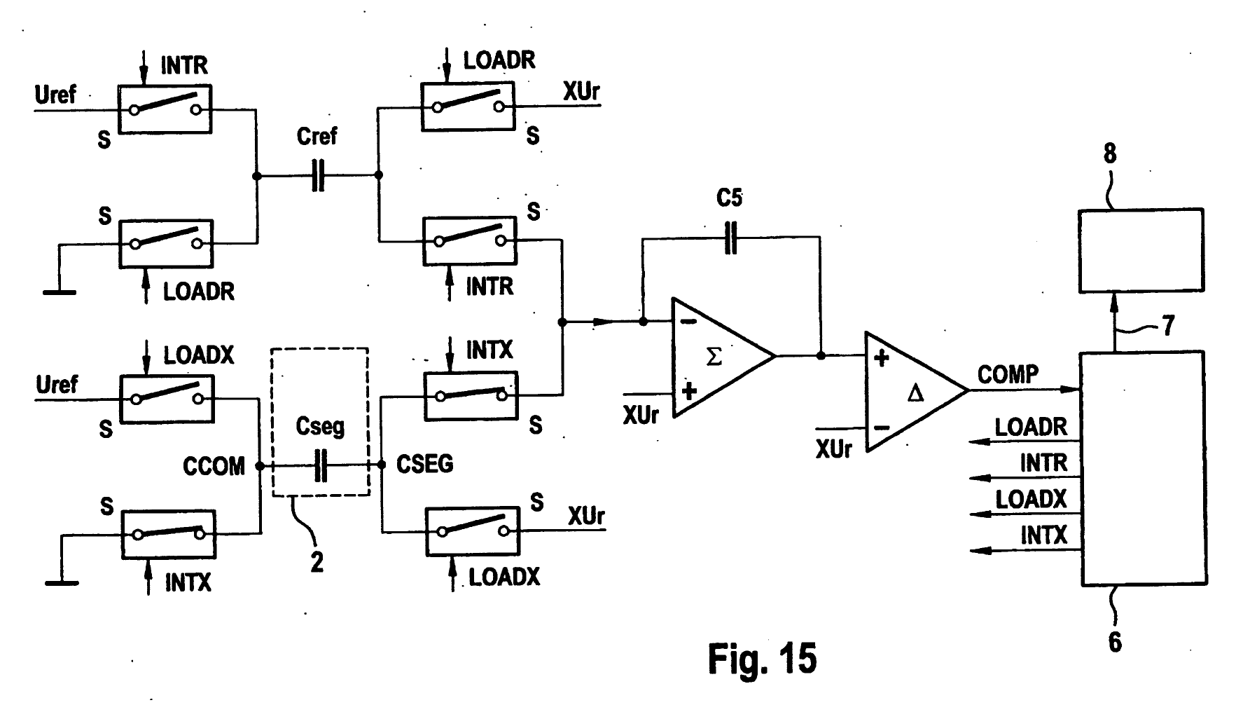

FIG. 15 shows the capacitance measuring circuit of FIG. 13 in the comparison phase without reference integration; and

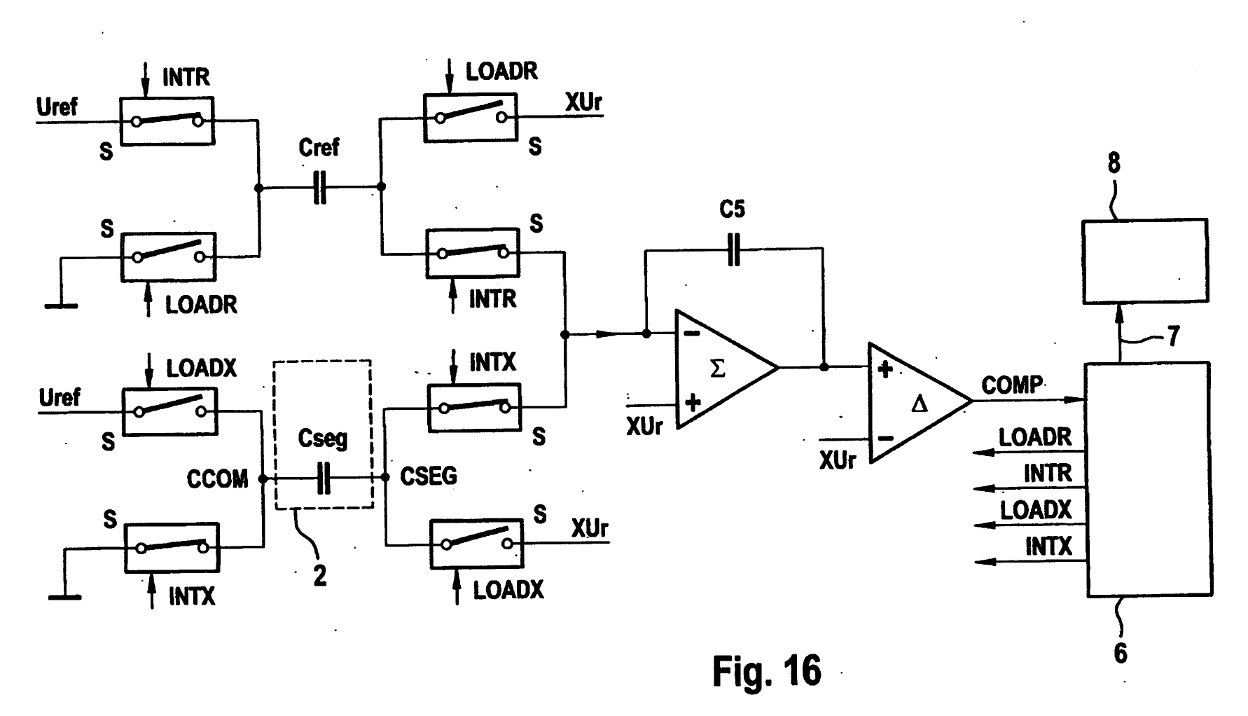

FIG. 16 shows the capacitance measuring circuit of FIG. 13 in the integration phase with reference integration.

FIG. 1 shows a functional diagram of an electronic measuring system according to the document, WO 95/14238, for the testing of LCD displays. The circuit cooperates with common driver ICs of the LCD triggering and comprises two switches S1 and S2, one inverter 1, and one voltage source U. During a specific test mode, the flow of current through the LCD segment to be tested, illustrated by the capacitance Cseg, is guided through a shunt resistor RS. The voltage drop at this shunt resistor RS is amplified by means of amplifier V and stored for the time being in a sample and hold element (S&H). A comparator Δ compares the output voltage of the sample and hold element to a reference voltage Uref and feeds the result of the comparison to the microprocessor μP that switches the switches S1 and S2 periodically. The microprocessor μP changes the keying frequency until the comparator signal shows pronounced signal changes (jitter). The frequency at which this event occurs is then used to deduce the capacitance Cseg of the display segment tested.

This circuit is associated with the disadvantages described above. Moreover, the structure of the LCD driver IC is unknown and no information regarding the impedances at the individual LCD segments is provided.

FIG. 2 shows an LCD testing circuit according to document EP 0 015 914 B1 for testing segment capacitances Cseg. It includes that series resistors Rv are placed in the lines leading to the LCD segments thus forming an RC low-pass filter, to which a voltage is applied by means of an oscillator Os. If the LCD functions properly, the rise time of this low-pass filter must be larger than a reference value for the corresponding type of display. The rise time is analyzed by means of the gate circuit Ts, comparator Δ, and reference voltage source Uref. Here, the output signal of the comparator Δ indicates whether the voltage on the segment capacitance exceeds the value Uref. The gate circuit Ts measures the time needed for this process.

One disadvantage of this known circuit is that both the gate circuit Ts and the series resistors Rv must be adjusted to the segment capacitances Cseg of the type of display to be tested.

FIG. 3 shows a schematic diagram of a modern ΔΣ converter operating with multiple oversampling and at 1-bit resolution. It consists of two blocks, namely an analog modulator and a digital filter. In principle, the modulator is an analog comparator Δ downstream from a low-pass filter acting as integrator Σ. Simultaneously, the input voltage Uin removes by means of the difference amplifier DV the output signal that is reconverted by a 1-bit digital-analog converter DAW such that the comparator Δ is reset each time. This produces a 1-bit data stream. If the amplitude of the analog signal increases, “1” predominates at the output of the comparator Δ. If it decreases, “0” predominates. If the amplitude is constant, “0” and “1” are balanced.

The analog signal could now be recovered directly by integration or by means of a simple low-pass filter. Noise-shaping can be used to obtain an improved signal-to-noise ratio, in which a noise spectrum is generated, for example by a noise source being included upstream from the integrator Σ. Subsequently, down-sampling is performed by an averaging, steep-flanked digital filter FIR.

FIG. 4 shows a schematic diagram of a preferred measuring arrangement according to the invention for determining the capacitance Cseg of an LCD display segment based on a ΔΣ capacitance measuring method that is also called ΔΣ conversion. In principle, this corresponds to a charge pump. The segment capacitance Cseg to be determined and a reference capacitor Cref whose capacitance is known are integrated in a switch/capacitor structure according to FIG. 4. The measuring arrangement comprises switches Sa, Sb, Sc, Sd and a downstream integrator Σ with integration capacitor C5 and downstream comparator Δ. The integration capacitor C5 should be selected sufficiently large to ensure that the integrator Σ does not reach its limits at the maximal segment capacitance Cseg to be expected and given recharging voltage swing ±Uref.

The switches, Sa to Sd, are controlled by a sequence control that is not shown here. During each switching process, an amount of charge corresponding to the capacitance is transferred and integrated by the downstream integrator Σ. In the process, the switches Sa-Sd are controlled by the sequence control such that a charge transfer through the reference capacitor Cref effects a decrease and a charge transfer through the segment capacitance to be determined effects an increase in the integrator voltage.

The charge balance of the integrator Σ is monitored by means of the downstream camparator Δ and can be kept constant by the sequence control by the option of transferring charge either through both capacitances or only through one of the capacitances. The ratio of the number of switching processes (or the added-up switching times) of the reference capacitance Cref and segment capacitance Cseg resulting for an even charge balance provides a digital result. A decimation filter implemented as a digital device is used to minimize the number of switching processes required to achieve a given accuracy of measurement.

Practical embodiments of LCD displays are usually triggered in a matrix structure using a multiplex procedure. FIG. 5 illustrates an equivalent electrical circuit diagram of an LCD with 9 segment electrodes and 4 back electrodes, i.e. with 36 segments in a 4×9 matrix structure, triggered by four line signals COM1, COM2, COM3, and COM4 and nine column signals SEG1 to SEG9. Segment capacitances and parasitic coupling capacitances are shown.

However, the drawing cannot show all possible coupling capacitances. The equivalent electrical circuit diagram of the LCD is based on a simplified model that was established based on the following presumptions:
1. The front and back electrodes are low-resistance in the frequency range considered. Accordingly, their impedance is neglected as compared to the coupling effects of the LCD segments.
2. The electrical conductivity of the liquid crystals is negligible.
3. Only coupling capacitances between neighboring segment and/or back electrodes are being considered. This presumption is a good approximation.

The capacitances of the individual segments between the front and back electrodes are C11 . . . C49. The coupling capacitances between the segment electrodes are CS12 . . . CS89, and the coupling capacitances between the back electrodes are CC12 . . . CC34. For testing of an individual segment, the measuring method should provide for measurement of the segment capacitances C11 . . . C49 individually and without mutual interference or interference by the capacitances C12 . . . C89 or CC12 . . . CC34.

Through the use of a measuring-circuit selector it becomes possible to select individual segments for functional testing and all but completely exclude any influence of parasitic coupling capacitances between the segments. Accordingly, the testing method is suitable for basically all types of LCD displays including those whose segment electrodes are arranged in a matrix structure. The function of the measuring-circuit selector shall be illustrated in the following based on an LCD display with a 2×2 matrix.

FIG. 6 illustrates a 2×2 matrix structures of this type using, as an example, an LCD display with four display segments whose capacitances are shown as C11, C12, C21, and C22. The segments are triggered by two line signals COM1, COM2 and two column signals SEG1, SEG2. The matrix further comprises parasitic coupling capacitances Cc and Cs; thus, all (significant) coupling capacitances are illustrated.

FIG. 7 shows a two-terminal representation of the 2×2 matrix of FIG. 6. The capacitance C11 is to be measured in an example, i.e. the ΔΣ converter is placed between the lines, SEG1 and COM1. The current Iv denotes the current flowing into the integrator, i.e. into the virtual mass. The two-terminal representation of FIG. 7 shows that not only the capacitance C11 to be measured contributes to the current Iv, but also the bridge circuit formed by the other capacitances shown in the circuit. This would falsify the measuring result.

The problem can be solved by using a measuring-circuit selector that connects all other lines of the matrix, i.e. the lines SEG2 and COM2 in this example, to earth as shown in FIG. 8. As a consequence, the parasitic current flows off towards earth and does not contribute to the current Iv and/or the measuring result. A corresponding procedure is also feasible with larger matrices, such as the matrix shown in FIG. 5.

The LCD shown in FIG. 5 consists of a matrix of many mutually coupling capacitances. If one wished to measure, for example, the capacitance of the segment C35 on the electrodes COM3 and SEG5, one would not measure just the capacitance C35 alone, but the other LCD capacitances as well due to the existing connections. This falsifies the measurement. In contrast, through the use of a measuring-circuit selector it becomes feasible to measure one certain capacitance, e.g. C35, in an isolated fashion, by ensuring through the use of the measuring-circuit selector that any currents flowing through capacitances other than the capacitance to be measured do not contribute to the capacitance measurement.

Isolated measurement of a segment, in particular by means of capacitive coupling of charges, at the junction of a certain front and back electrode can be achieved in particular by the measuring-circuit selector meeting the following conditions:
1. An alternating voltage is applied to the front electrode leading to the segment to be measured.
2. The other front electrodes are connected to earth in terms of alternating voltage.
3. The charge coupled over is measured on the back electrode leading away from the segment to be measured, whereby this point is at virtual earth in terms of alternating voltage.
4. All other back electrodes are connected to earth in terms of alternating voltage.

The front and back electrodes can be mutually exchanged. However, it is more advantageous electrically to arrange as few circuit components as possible on the side at which the charge is sampled.

If, for example, the segment capacitance C35 in FIG. 5 is to be measured, the alternating voltage is applied at SEG5. The terminal connections SEG1 to SEG4 and SEG6 to SEG9 are connected to earth. As a consequence, there is no influence of any of the parasitic capacitances between neighboring segment electrodes CS12 . . . CS89 or between not directly neighboring segment electrodes. Although these capacitances cause a somewhat stronger draw on the applied alternating voltage; the fault current flows off toward earth. The flow of current into the virtual earth is measured at electrode COM3 and used to determine the capacitance C35. The electrodes COM1, COM2, and COM4 are connected to earth such that no cross-currents can flow in the coupling capacitances between the back electrodes CC12 . . . CC34. Consequently, CC12 . . . CC34 have no effect on the measurement.

With the exception of C35, all other segment capacities C11 . . . C49 have no influence on the measurement, since the circuiting described above including the measuring-circuit selector connects all segment capacitances other than C15, C25, C35, and C45, to earth or virtual earth on both sides such that no current flows through these elements. The currents flowing through C15, C25, and C45 flow off towards earth and thus do not contribute to the capacitance measurement either. Taken together, the LCD circuiting described above including a measuring-circuit selector allows for measurement of individual LCD segments in the matrix.

A measuring-circuit selector of this type preferably consists of digitally triggered analog multiplexers in a mixed CMOS-Schottky diode switch technology. Provided the distance to the LCD to be measured is kept short, these possess only negligible inherent parasitic capacitance. In the case depicted in FIG. 6, a measuring-circuit selector has nine positions, for example for coupling-in of the stimulus, and five positions for measuring the charge, four of which are for the terminal connections COM1 to COM4, and one position is for connecting the calibration or reference capacitor, that is supplied with the stimulus on its other end at all times.

The influence of coupling capacitances in LCDs triggered in the multiplex procedure can also be counteracted by triggering with a low output impedance.

In order to not have to turn off the LCD display during the functional test, it is feasible to integrate the function of the measuring-circuit selector into the LCD driver circuit, which preferably is implemented in the form of an ASIC, such that the functional test of the LCD display segments is performed during the ongoing display operation. This is based on the fact there are certain degrees of freedom with regard to the sequence of switch actuations of the ΔΣ conversion and measuring-circuit selector as well as in the selection of the charge transfer voltage values allowing for synchronization of the switching processes to the LCD driver clock rate. As a consequence, it is feasible to perform the functional test of the LCD display segments during the ongoing display operation without disturbance, interference or interruption of the display. This shall be illustrated in more detail in the following.

LCD displays whose segment and back electrodes are arranged in the form of a matrix are addressed in time-division multiplex operation, since it is not possible to select all segments concomitantly. In this context, inactive segments cannot be triggered absolutely free of voltage due to the matrix structure. This is illustrated in FIGS. 9 and 10.

FIG. 9 shows four display segments 2, 3, 4, and 5 arranged in an exemplary fashion in a square arrangement of square display segments. Segment 2 is activated (black), which means it displays a black square, whereas segments 3, 4, and 5 are not activated (white). The display segments, 2, 3, 4, 5, are triggered electrically in the form of a matrix according to FIG. 6.

FIGS. 6 and 7 show that a flow of current through one of the capacitances, C12, C21 or C22, always occurs even upon variation of the voltage levels at COM2 or SEG2. In practical application, this problem is solved by adequate triggering of the trigger voltage level and clock phases such that the voltage level on inactive segments is below the response threshold and the voltage level on active segments is above the response threshold of the liquid crystals. A common multiplex triggering of this type by means of a common LCD driver IC for the LCD of FIG. 9 is shown in FIG. 10.

As shown in FIG. 10, ternary signals are applied to the COM electrodes, which each can assume voltage values of 0, 0.5 Ur or Ur. Binary signals assuming one of the voltage values, XUr or (1-X)Ur, are applied to each of the SEG electrodes. The coefficient X, with 0<X<0.5, is selected such that the voltage level required for activation of an LCD segment is established only at maximal resulting voltage excursion, i.e. at the two level combinations Ur, (1-X)Ur and 0, XUr. Periodical reversal of the polarity, shown in FIG. 10 by the vertical dashed line, is used to achieve triggering that is direct voltage-free on average. An LCD driver circuit meeting these requirements is shown schematically in FIG. 11.

A ΔΣ converter employed for functional testing of LCD display segments can be designed such that it operates at the voltage levels required for multiplex operation and its switching phases are synchronized with the clock phases of the LCD triggering. As before, on average direct voltage-free triggering of the LCD segments can be implemented.

The trigger frequency of an LCD display usually is between 30 and 100 Hz. The measuring frequency of a capacitance measuring method according to the invention, of a ΔΣ converter for example, preferably is higher than 2 kHz, preferably is higher than 5 kHz, and particularly preferably is higher than 10 kHz. Accordingly, a sufficient number of ΔΣ converter switching processes can be made in the LCD trigger clock phases of LCD triggering to allow the capacitance measurement and therefore the functional test to be performed while display is ongoing. In this context, it is advantageous to perform functional testing such that the effective values of the LCD segment voltages are the same as in the absence of the functional test in order for there to be no difference between the display with ongoing functional testing and the display without functional testing.

FIG. 12 shows a corresponding LCD driver circuit with integrated ΔΣ converter. The voltages on the COM terminal connections are constantly sampled at the measuring clock speed of the ΔΣ converter. The voltage, U0, is then to be selected such that the effective value of the segment voltage becomes identical to Ur. According to the example shown in FIGS. 9 and 10, voltage Ur and coefficient X introduced therein depend on the LCD response threshold. The additional modulation of the LCD triggering voltage by the measuring clock rate causes a reduction in the effective value of the trigger level which is the significant parameter for LCD activation. Therefore voltage U0 is always to be selected larger than voltage Ur depending on the pulse/pause ratio of the measuring clock rate. In the circuit shown in FIG. 12, a capacitance measurement is performed only at UCOM=U0 in order to avoid the additional circuitry.

In the circuit according to FIG. 12, a complete switching cycle consists of three consecutive main phases, namely a charge phase, a comparison phase, and an integration phase. Moreover, there is a resting phase, in which all MOS switches are open. For each complete switching cycle, a single bit is obtained as an intermediary result. A large number of switching cycles of this type is required for a complete capacitance measurement on one LCD display segment. The capacitance is calculated from the sequence of single bits (the intermediary results) per switching cycle. The states of the switches, S1-S11, in FIG. 12 in various operating phases are identified in the following table.

| | Phase 1 | Phase 2 | Phase 3 | Phase 4 | Phase 5 | Phase 6 |
|---|---|---|---|---|---|---|
| S1 | 1 | 0 | 0 | 0 | 0 | 0 |
| S2 | 0 | 1 | 1 | 0 | 1 | 1 |
| S3 | 0 | 0 | 0 | 1 | 0 | 0 |
| S4 | 0 | 0 | 1 | 0 | 0 | 0 |
| S5 | 1 | 0 | 0 | 0 | 0 | 0 |
| S6 | 1 | 0 | 0 | 1 | 1 | 1 |
| S7 | 0 | 1 | 1 | 0 | 0 | 0 |
| S8 | 0 | 0 | 1 | 0 | 0 | 0 |
| S9 | 1 | 0 | 0 | 0 | 0 | 0 |
| S10 | 0 | 0 | 0 | 1 | 0 | 1 |
| S11 | 1 | 0 | 0 | 0 | 1 | 0 |

In the table:
0 = switch is open
1 = switch is closed
Phase 1 = segment is active, polarity +, charge phase
Phase 2 = segment is inactive, polarity +, integration without reference integration
Phase 3 = segment is active, polarity +, integration with reference integration
Phase 4 = segment is active, polarity −, no measurement performed
Phase 5 = segment is inactive, polarity +, no measurement performed
Phase 6 = segment is inactive, polarity −, no measurement performed

The sequence of switch phases can be modified. However, it should be ensured that all phases are of sufficient duration for recharging the capacitors, Cseg and Cref, and the integrator Σ has sufficient time for recovery. The duration of the individual switch phases should also account for the corresponding series resistance in the recharge circuits. Although these series resistances exert no direct influence on the measuring result, they may falsify the result if the switch phases are too short to allow for sufficient charge balance. The MOS switches should be triggered in a suitable fashion in order to prevent cross-currents via switches that are still closed or already closed. For this purpose, the “break-before-make” concept is available or additional phases of shifted trigger signals can be used.

In the beginning of the integration phase, starting from the state of “all switches open”, the integrator Σ should first be connected to the non-driven terminal connections of Cseg and Cref prior to the recharging, i.e. the switches shown to the right of Cseg and Cref should close before the switches shown to the left thereof. Unless this is done, there is a risk of partial discharge via parasitic diodes in the MOS structure leading to measuring errors and, if the pulse currents are large, possibly to a latch-up which may lead to functional failure or destruction of the ASIC.

The measuring accuracy can be improved by using MOS switches and operational amplifiers comprising no input protection diodes. If the integrator recovers too slowly, these might cause part of the charge to leak through these diodes at the start of the integration phase which would lead to a measuring error.

The reference capacitor usually should be higher than the largest expected segment capacitance Cseg, since “charge balancing” does not proceed correctly otherwise. However, it is also feasible to use a smaller reference capacitor Cref by modifying the switch cycles.

The digital ΔΣ converter result is used for the functional test of the LCD display segment. Numerous functional test criteria can be realised, e.g. the relative ratio of segment capacitances or the compliance with absolute limits of capacitance values.

FIG. 13 shows an electrical block diagram of a capacitance measuring circuit at rest that corresponds to FIGS. 4 and 12 in principle, but is modified somewhat in detail, i.e. for trigger signals of switches S with a logic value of 0. The measuring-circuit selector is not shown, and with regard to wiring it is presumed that a certain display segment 2 is addressed by the measuring-circuit selector in order to measure its segment capacitance Cseg. This segment capacitance, Cseg, is shown between the signal lines CCOM and CSEG.

FIG. 12 shows an LCD driver circuit that, on the one hand, supplies the voltage levels required for correct LCD display operation, and, on the other hand, permits a capacitance measurement of active segments according to the ΔΣ method described above, whereby voltage level and clock signals are controlled such that display and capacitance measurements can be performed simultaneously. FIG. 13 refers to a capacitance measuring circuit used therein.

According to FIG. 13, the capacitance measurement is performed by ΔΣ conversion with the reference capacitor Cref. The capacitances, Cseg and Cref, each are connected to a full bridge circuit consisting of four MOS switches S, whereby the switches are controlled by sequence control 6 using logic signals LOADR, LOADX, INTR, and INTX. This allows to charge the capacitances, Cseg and Cref, under separate control and/or to recharge them controlled by the inverting integrator Δ comprising a MOS operational amplifier and the integration capacitor CS.

The output voltage of the integrator Σ is compared by means of the comparator Δ to the voltage XUr, whereby the comparator Δ supplies the logic signal COMP. This signal is equal to a logic value of 1 if the integration voltage supplied by the integrator Σ is higher than XUr. The downstream sequence control 6, which, for example, is integrated into an ASIC or implemented in the form of software by means of a microcontroller, controls the switches S by means of the logic signals, LOADR, LOADX, INTR, and INTX. Also shown are the resulting 1-bit data stream 7 and the decimation filter 8.

FIG. 14 shows the capacitance measuring circuit of FIG. 13 in the charge phase, in which the capacitors Cseg and Cref are being charged, and in the subsequent short comparison phase, in which the output COMP of the comparator Δ is sampled and tested whether the integration voltage increased or decreased. If COMP is equal to a logic value of 0, an integration phase without reference integration follows, whereas, if COMP is equal to a logic value of 1, an integration phase with reference integration follows.

The integration phase without reference integration is shown in FIG. 15 and the integration phase with reference integration is shown in FIG. 16. The segment capacitance Cseg of interest can be determined from the charge balance.

### LIST OF REFERENCE NUMBERS

1 Inverter
2 Display segment
3 Display segment
4 Display segment
5 Display segment
6 Sequence control
7 1-bit data stream
8 Decimation filter
Cc Coupling capacitance
Cmn Display segment
C11 . . . C49 Segment capacitances
COM Line signal
COMP Logic signal
Cref Reference capacitor
C5 Integration capacitor
Cs Coupling capacitance
Cseg Segment capacitance
DAW Digital-analog converter
DV Difference amplifier
FIR Digital filter
Iv Integrator current
LOADR Logic signal
LOADX Logic signal
INTR Logic signal
INTX Logic signal
Os Oscillator
μP Microprocessor
RS Shunt resistor
Rv Series resistor
S&H Sample & hold element
SEG Column signal
S Switch
Ts Gate circuit
U Voltage source
U0 Voltage level of combined LCD multiplex and measuring operation
Ur Voltage level of LCD multiplex operation
Uin Input voltage
Uref Reference voltage
V Amplifier
Δ Comparator
Σ Integrator (low-pass)
X Factor

1-45. (canceled)

46. A method for testing the function of LCD displays comprising individual display segments, based on the difference in the electrical capacitance of defective and intact display segments, wherein the display segments of the LCD display are directly coupled to the segment electrodes and back electrodes, the method comprising the steps of:
determining the capacitance (Cseg) of the display segments directly with a capacitance measuring method by measuring the electrical charge stored in the display segment, wherein a charge transfer controlled by a sequence control proceeds through both the capacitance of a display segment to be measured and a reference capacitor (Cref), and for testing the function of the display segment the capacitance of the display segment is determined using a charge balance ratio between the display segment to be tested and the reference capacitor (Cref).

47. The method according to claim 46, wherein the capacitance of the display segments is determined by means of charges transferred by capacitive coupling, whereby an electrical measuring current is coupled capacitively via the capacitance (Cseg) of the display segment to be measured into an evaluation circuit and the evaluation circuit measures the charge coupled over.

48. The method according to claim 46, wherein the reference capacitor (Cref) is integrated into the LCD display.

49. The method according to claim 46, wherein the capacitance of the display segments (2, 3) is determined by means of a capacitance measuring method utilizing a ΔΣ conversion.

50. The method according to claim 46, wherein an automatic measuring-circuit selector is used to address individual display segments for testing the function of the segments.

51. The method according to claim 50, wherein the measuring-circuit selector is used to apply a measuring voltage to a first electrode of a display segment to be tested, to connect the electrodes of other display segments corresponding to the first electrode to earth in terms of alternating voltage, to measure the coupled charge on the second electrode of the display segment to be tested, whereby this point is connected to virtual earth in terms of alternating voltage, and to connect the electrodes of other display segments corresponding to said second electrode to earth in terms of alternating voltage.

52. The method according to claim 46, wherein the display segments are triggered in a matrix structure using a multiplex procedure both for the ongoing operation of the LCD display and the testing of the function of the segments.

53. The method according to claim 52, wherein triggering levels and clock phases for triggering the display segments, in particular in the multiplex procedure, are selected such that the voltage level of inactive display segments is below a response threshold and the voltage level of the active display segments is above the response threshold of the display segments, the capacitance measuring method is performed using these voltage levels, and the switch phases of the capacitance measuring method are synchronized with the clock phases of LCD triggering.

54. The method according to claim 52, wherein the display segments are triggered direct voltage-free, on average, by periodically reversing the polarity of the voltage levels.

55. The method according to claim 52, wherein the LCD display is triggered at low impedance for at least one of the ongoing operation and capacitance measurement in order to reduce the influence of coupling capacitances.

56. The method according claim 46, wherein the capacitance measuring method is performed such that the effective voltage value of the display segments is substantially identical to the value without measurement of the capacitance.

57. The method according to claim 46, wherein the capacitance of the display segments is determined by means of the capacitance measuring method in the form of a digital measuring result and the testing of the function of a display segment is performed using the digital measuring result.

58. The method according to claim 46, wherein the testing of the function of the display segment is performed during the ongoing operation of the LCD display.

59. The method according to claim 58, wherein the sequence control for the capacitance measurement and a measuring-circuit selector for triggering a display segment is one of modulated by and synchronized with the driver circuit of the LCD display.

60. The method according to claim 59, wherein one or more of the following components are housed in a single integrated component: the sequence control for the capacitance measurement, the measuring-circuit selector for triggering of a display segment, the measuring circuit, the LCD driver/decoder circuit, and the analytical circuit.

61. The method according to claim 46, wherein only activated display segments are tested for function.

62. An electronic measuring system for testing the function of LCD displays comprising individual display segments, based on the difference in the electrical capacitance of defective and intact display segments, wherein the display segments of the LCD display are directly coupled to the segment electrodes and back electrodes, the electronic measuring system comprising:
a capacitance measuring facility that allows the capacitance (Cseg) of the display segments to be determined directly with a capacitance measuring method by measuring the electrical charge stored in the display segment; and
an electronic circuit for measuring the capacitance of the display segments with the capacitance measuring method, in which a charge transfer controlled by a sequence control proceeds through both the capacitance of a display segment to be measured and a reference capacitor (Cref), and wherein for testing the function of the display segment the capacitance of the display segment is determined using a charge balance ratio between the display segment to be tested and the reference capacitor (Cref).

63. A diagnostic device for testing the function of LCD displays comprising individual display segments, based on the difference in the electrical capacitance of defective and intact display segments, wherein the display segments of the LCD display are directly coupled to the segment electrodes and back electrodes, the diagnostic device comprising:
a capacitance measuring facility that allows the capacitance (Cseg) of the display segments to be determined directly with a capacitance measuring method by measuring the electrical charge stored in the display segment; and
an electronic circuit for measuring the capacitance of the display segments with the capacitance measuring method, in which a charge transfer controlled by a sequence control proceeds through both the capacitance of a display segment to be measured and a reference capacitor (Cref), and wherein for testing the function of the display segment the capacitance of the display segment is determined using a charge balance ratio between the display segment to be tested and the reference capacitor (Cref).
